(19) United States
(12) Patent Application Publication
(10) Pub. No.: US 2025/0008800 A1
(43) Pub. Date: Jan. 2, 2025

(54) DISPLAY PANEL, METHOD FOR MANUFACTURING DISPLAY PANEL, AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Zengqiang XIA, Hefei (CN); Yuan YAO, Hefei (CN); Zhengkui DONG, Hefei (CN); Murong XUE, Hefei (CN); Chen XU, Hefei (CN); Yiming XIAO, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/883,850

(22) Filed: Sep. 12, 2024

Related U.S. Application Data
(63) Continuation of application No. PCT/CN2024/097619, filed on Jun. 5, 2024.

(30) Foreign Application Priority Data
Jun. 9, 2023 (CN) 202310692582.3

(51) Int. Cl. H10K 59/131; H10K 59/12; H10K 59/122

(52) U.S. Cl. CPC H10K 59/1315; H10K 59/1201; H10K 59/122

(57) ABSTRACT

The present application discloses a display panel, a method for manufacturing a display panel, and a display apparatus. The display panel includes a substrate, a plurality of first scanning lines, at least an isolation structure, and a plurality of light-emitting functional units, the plurality of first scanning lines are located on a side of the substrate and arranged along a first direction; the at least an isolation structure is formed on a side of the substrate and encloses and forms at least an opening portion, the at least an isolation structure includes a first isolation portion including a side surface facing a side of the at least an opening portion, the side surface includes a first surface, a plane where the first surface is located intersects a plane where the substrate is located to form a first intersection line.

### CROSS-REFERENCE TO RELATED APPLICATION

The present application is a continuation application of International Application No. PCT/CN2024/097619, filed on Jun. 5, 2024, which claims priority to Chinese Patent Application No. 202310692582.3 filed on Jun. 9, 2023, and titled “DISPLAY PANEL, METHOD FOR MANUFACTURING DISPLAY PANEL, AND DISPLAY APPARATUS”, all of which are hereby incorporated by reference in their entireties.

### TECHNICAL FIELD

The present application relates to the field of display technology, and particularly to a display panel, a method for manufacturing a display panel, and a display apparatus.

### BACKGROUND

Organic Light-Emitting Diode (OLED) are also known as an organic electroluminescent laser display or an organic light-emitting semiconductor. OLED gradually replaces a Liquid Crystal Display (LCD) display due to its low driving voltage, active light emission, wide viewing angle, high efficiency, fast response, and easy realization of full-color large-area wall-mount display, and flexible display.

With the development of display technology, performance requirements for display devices become higher and higher, and in the display devices of the related art, it is difficult for the performance of the display panels to meet user needs.

### SUMMARY

Embodiments of the present application provide a display panel, a method for manufacturing a display panel, and a display apparatus, which may improve a display quality of the display panel.

Embodiments of a first aspect of the embodiments of the present application provide a display panel including a substrate, at least an isolation structure, a plurality of first scanning lines, and a plurality of light-emitting functional units; the plurality of first scanning lines are located on a side of the substrate and arranged along a first direction; the at least an isolation structure is formed on a side of the substrate and encircles and forms at least an opening portion, the at least an isolation structure includes a first isolation portion including a side surface facing a side of the at least an opening portion, the side surface includes a first surface, a plane where the first surface is located intersects a plane where the substrate is located to form a first intersection line, and the first intersection line and the first direction form a first preset angle therebetween; the light-emitting functional unit is provided on the substrate and corresponds to the at least an opening portion, and the light-emitting functional unit includes a first electrode, a light-emitting functional layer, and a second electrode; and here, the second electrode is in contact with the at least an isolation structure, and the first preset angle is greater than or equal to 0°, and less than 45°.

Embodiments of a second aspect of the present application also provide a display panel including a substrate, at least an isolation structure, and a plurality of light-emitting functional units; the at least an isolation structure is formed on a side of the substrate and encircles and forms at least an opening portion; the light-emitting functional unit is provided on the substrate and corresponds to the at least an opening portion, and the light-emitting functional unit includes a first electrode, a light-emitting functional layer, and a second electrode; here, the second electrode is in contact with the at least an isolation structure, and an edge of an orthographic projection of the at least an isolation structure on the substrate is in a sawtooth shape.

Embodiments of a third aspect of the present application provide a display apparatus including any of the display panels according to the first aspect and the second aspect of the present application.

Embodiment of a fourth aspect of the present application provide a method for manufacturing a display panel, including:
providing a substrate;
forming at least an isolation structure on a side of the substrate, here, the at least an isolation structure encircles and forms at least an opening portion and includes a first isolation portion, the first isolation portion includes a side surface facing a side of the at least an opening portion, the side surface includes a first surface, a plane where the first surface is located intersects a plane where the substrate is located to form a first intersection line, and the first intersection line and a first direction form a first preset angle greater than or equal to 0°, and less than 45°;
forming a plurality of light-emitting functional units on the substrate, here, the light-emitting functional unit corresponds to the at least an opening portion, and forming the plurality of light-emitting functional units on the substrate includes: forming a first electrode on the substrate; forming a light-emitting functional layer on a side of the first electrode away from the substrate; forming a second electrode on a side of the light-emitting functional layer away from the substrate, here, forming the second electrode on the side of the light-emitting functional layer away from the substrate includes: providing an evaporation source including a plurality of evaporation holes arranged along a third direction; setting a positional relationship between the evaporation source and the substrate as the evaporation source being located on a side of the at least an isolation structure away from the substrate, here, the third direction is parallel to the first direction.

According to the implementations of the fourth aspect of the present application, the first preset angle is 0°.

According to the implementations of the fourth aspect of the present application, the side surface further includes a second surface, the second surface and the first surface are provided alternately along a direction around a center of the opening portion, the second surface is connected to the first surface, a plane where the second surface is located intersects the plane where the substrate is located to form a second intersection line, and the second intersection line and the first direction form a second preset angle greater than 45° and less than or equal to 90°.

According to any of the above implementations of the fourth aspect of the present application, a length of an intersection line of the second surface and the bottom surface is less than a length of an intersection line of the first surface and the bottom surface.

According to any of the above implementations of the fourth aspect of the present application, an edge of an orthographic projection of the first isolation portion on the substrate is in a sawtooth shape.

According to any of the above implementations of the fourth aspect of the present application, forming the second electrode on the side of the light-emitting functional layer away from the substrate further includes: moving the evaporation source along a preset direction, so that an evaporation material evaporated from the evaporation hole is formed on the first surface to form the second electrode in contact with the first surface, here, the preset direction is parallel to the plane where the substrate is located and perpendicular to the first direction.

According to any of the above implementations of the fourth aspect of the present application, the method further comprises: forming a plurality of first scanning lines on a side of the substrate, here, the plurality of first scanning lines are arranged along the first direction.

The display panel according to the present application includes the substrate, the plurality of first scanning lines, the isolation structure, and the plurality of light-emitting functional units. The plurality of first scanning lines are formed on the side of the substrate and arranged along the first direction to achieve scanning of a driving circuit corresponding to the light-emitting functional unit. The isolation structure is formed on the side of the substrate and encircles and forms the opening portion, the light-emitting functional unit is formed within the opening portion, and the light-emitting functional unit includes the first electrode, the light-emitting functional layer, and the second electrode stacked along a direction away from the substrate. The isolation structure includes the first isolation portion including the side surface facing the side of the opening portion, and the side surface includes the first surface and may further include other surfaces intersecting with the first surface, which is not limited in the present application. The plane where the first surface is located intersects the plane where the substrate is located to form the first intersection line. Specifically, the first intersection line may be an edge line of the first surface close to a terminal of the substrate. In a manufacturing process, an arrangement direction of various evaporation holes on the evaporation source configured to evaporate the second electrode is often parallel to the first direction. In the display panel according to the present application, the first intersection line and the first direction forms the first preset angle, and the first preset angle is set to be greater than or equal to 0°, and less than 45°, so that an evaporation material evaporated from evaporation holes in the evaporation source arranged along a direction parallel to the first direction may be distributed uniformly on the first surface. Specifically, the “uniformly” means a strong consistency in a thickness distribution along the first intersection line in the first surface, and uniformity of the thickness distribution of a contact portion between the second electrode formed by the evaporation material and the first surface is increased, so that the resistance of various regions of second electrodes arranged along a first intersection line direction is more uniform. Meanwhile, an actual evaporation angle is relatively great, so that a height of the second electrode on the first surface is increased, a contact area between the isolation structure and the second electrode is increased, brightness uniformity of light emitted by various parts of the light-emitting functional unit is enhanced, the resistance is reduced, and contact stability is increased, which is helpful to improve a display quality of the display panel.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 is a schematic view of an evaporation process in the related art;

FIG. 2 is a schematic structural view of a side surface of an isolation structure in the related art;

FIG. 3 is a top view of FIG. 1;

FIG. 4 is a partial schematic view of FIG. 3;

FIG. 5 is a schematic cross-sectional view along N-N′ in FIG. 3;

FIG. 6 is a schematic structural view of a side surface of an isolation structure in the related art;

FIG. 7 is a top view of a display panel according to the present application;

FIG. 8 is a top view of the region Q in FIG. 7;

FIG. 9 is an enlarged view of the region Q in FIG. 7;

FIG. 10 is a cross-sectional view along P-P′ in FIG. 7;

FIG. 11 is a schematic view of a display panel in a manufacturing process according to the present application;

FIG. 12 is another top view of the region Q in FIG. 7;

FIG. 13 is another top view of the region Q in FIG. 7;

FIG. 14 is another top view of the region Q in FIG. 7;

FIG. 15 is another cross-sectional view along P-P′ in FIG. 7;

FIG. 16 is another cross-sectional view along P-P′ in FIG. 7;

FIG. 17 is another top view of the region Q in FIG. 7;

FIG. 18 is another top view of the region Q in FIG. 7;

FIG. 19 is a schematic structural view of a display apparatus according to the present application; and

FIG. 20 is a flow chart of a method for manufacturing a display panel according to the present application.

### REFERENCE NUMERALS

1: Display panel; 11: Substrate; 110: Driving circuit layer; 111: First scanning line; 12: Light-emitting layer; 121: Light-emitting functional unit; 1211: First electrode; 1212: Light-emitting functional layer; 1213: Second electrode; 1214: First part; 1215: Second part; 1216: First light-emitting functional unit; 1217: Second light-emitting functional unit; 1218: Third light-emitting functional unit; 13: Isolation structure; 131: Opening portion; 132: First isolation portion; 1320: First surface; 1321: Top surface; 1322: Bottom surface; 1323: Side surface; 1325: First intersection line; 1324: First cross section; 1326: Second surface; 1327: Second intersection line; α2: Second preset angle; 133: Second isolation portion; 14: First virtual quadrilateral; x: First direction; c1: First angle; 2: Evaporation source; y: Second direction; m: Preset direction; 17: Pixel definition layer; 171: Pixel definition portion; 172: First opening; 173: Groove; 174: Second opening; 175: Quadrilateral; 176: Circle; 18: Second virtual quadrilateral; 3: Display apparatus.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely intended to provide a better understanding of the present application by illustrating examples of the present application.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

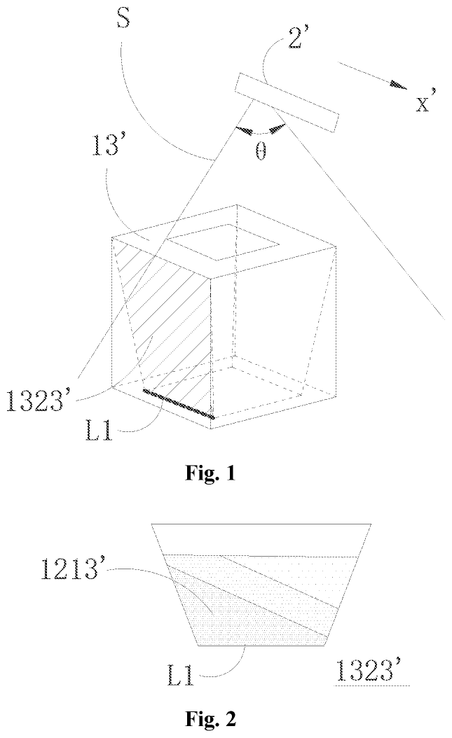

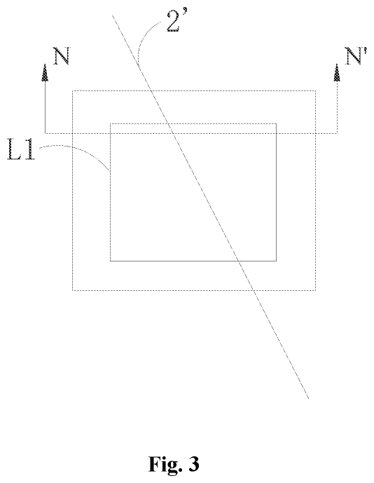

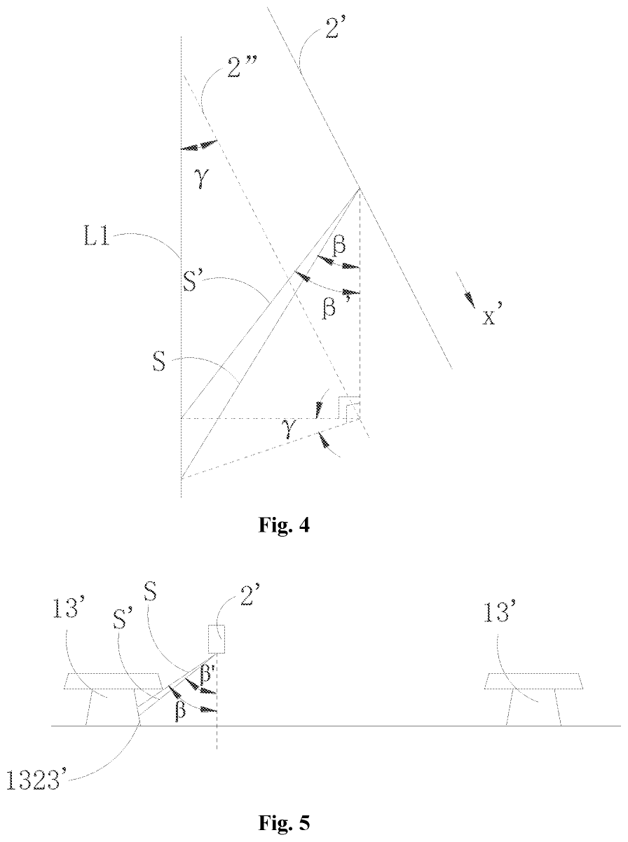

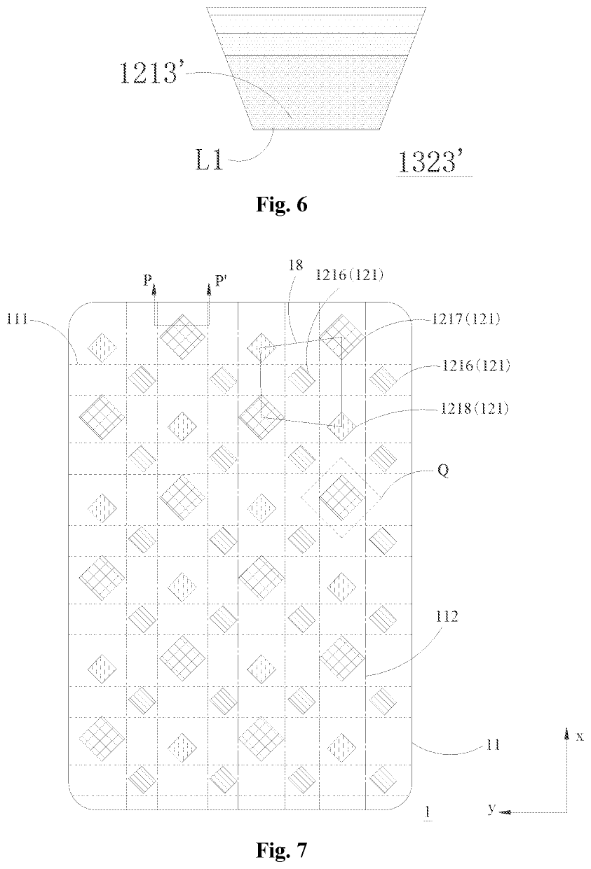

The applicant has found that the display panel includes a substrate, a light-emitting functional unit, and at least an isolation structure 13′, and the isolation structure 13′ encircles and forms at least an opening portion configured to accommodate the light-emitting functional unit. The light-emitting functional unit is located on a side of the substrate and includes a first electrode, a light-emitting functional layer, and a second electrode 1213′ stacked along a direction away from the substrate, and second electrodes 1213′ of adjacent light-emitting functional units are electrically connected through isolation structures 13′. The second electrode 1213′ is manufactured using an evaporation process, an evaporation source 2′ includes a plurality of evaporation holes arranged along a first direction x′, and in the evaporation process, the evaporation source 2′ moves along a preset direction, here, the preset direction is parallel to a plane where the display panel is located and perpendicular to the first direction x′. As shown in FIG. 1, under a condition that an orthographic projection of the opening portion on the substrate is a rectangular ring structure, the opening portion includes four side walls 1323′ facing inside the opening portion. Under a condition that an intersection line L1 formed by a plane where the side wall 1323′ is located and a plane where the substrate is located is not parallel to the first direction x′, that is, the intersection line L1 formed by the plane where the side wall 1323′ is located and the plane where the substrate is located intersects the first direction x′, as shown in FIG. 2, uniformity of a thickness distribution of evaporation materials distributed within various regions arranged along the intersection line L1 direction in the side wall 1323′ is poor. Meanwhile, as shown in FIG. 3 and FIG. 4, an actual evaporation angle of the evaporation source (S′ in FIG. 4 represents an edge of an actual maximum distribution range of the evaporation material, and the actual evaporation angle is related to S′) may be less than an original evaporation angle θ of the evaporation source (S in FIG. 3 represents an edge of an original maximum distribution range of the evaporation material, and the original evaporation angle is related to S), here, the original evaporation angle θ refers to an angle between two maximum evaporation paths on a section perpendicular to the first direction x′, and the actual evaporation angle of the evaporation source refers to an angle between two maximum evaporation paths on the direction perpendicular to the plane of L1. Specifically, as shown in FIG. 4, half of the evaporation angle θ and half of the actual evaporation angle θ′, that is, β and β′, are shown in FIG. 4, here, under a condition that the first direction x′ and the intersection line L1 form an angle γ, it may be obtained from FIG. 4 that tan β′/tan β=cos γ, that is, the actual evaporation angle 2β′ is less than the original evaporation angle 2β of the evaporation source, so that, as shown in FIG. 5, the height of the second electrode on the side wall 1323′ is relatively small. As shown in FIG. 6, under a condition that the intersection line L1 is parallel to the first direction x′, in a process of the evaporation source 2′ moving along a direction parallel to the plane where the display panel is located and perpendicular to the first direction, formation of the evaporation material with a relatively great height and a relatively uniform thickness on two opposite side walls 1323′ may be achieved, so that the second electrode 1213′ having a relatively great overlapped area with the isolation structure 13′ and a relatively uniform thickness is formed. However, in order to achieve a desired display effect, a shape and an arrangement of pixels in the existing display panel need to be designed, but a position of the evaporation source 2′ is fixed, an adjustment is inconvenient, and adjustment cost is high, so that the intersection line L1 and the first direction x′ in the display panel are not parallel, that is, the intersection line L1 and the first direction x′ in the display panel intersect, and the second electrode 1213′ with a relatively low height and a non-uniform thickness is formed on the side wall 1323′, thereby affecting the resistance, power consumption, and the display quality of the display panel. Based on the study of the above problems, the applicant has provided a display panel, a method for manufacturing a display panel, and a display apparatus to reduce the resistance of the display panel, thereby reducing the power consumption of the display panel and improving the display quality of the display panel.

For a better understanding of the present application, a display panel and a display apparatus according to embodiments of the present application will be described in detail below with reference to FIG. 7 to FIG. 12.

Referring to FIG. 7 to FIG. 10, the embodiments of the present application provides a display panel 1 including a substrate 11, a plurality of first scanning lines 111, an isolation structure 13, and a plurality of light-emitting functional units 121. The plurality of first scanning lines 111 are located on a side of the substrate 11 and arranged along a first direction x. The isolation structure 13 is formed on a side of the substrate 11 and encircles and forms an opening portion 131, the isolation structure 13 includes a first isolation portion 132 including a side surface 1323 facing a side of the opening portion 131, the side surface 1323 includes a first surface 1320, a plane where the first surface 1320 is located intersects a plane where the substrate 11 is located to form a first intersection line 1325, and the first intersection line 1325 and the first direction x form a first preset angle therebetween. The light-emitting functional unit 121 is provided on the substrate 11 and corresponds to the opening portion 131, and includes a first electrode 1211, a light-emitting functional layer 1212, and a second electrode 1213. Here, the second electrode 1213 is in contact with the isolation structure 13, and the first preset angle is greater than or equal to 0°, and less than 45°.

Specifically, a driving circuit layer 110 may be formed on a side of the substrate 11, and the first scanning line 111 is formed within the driving circuit layer 110.

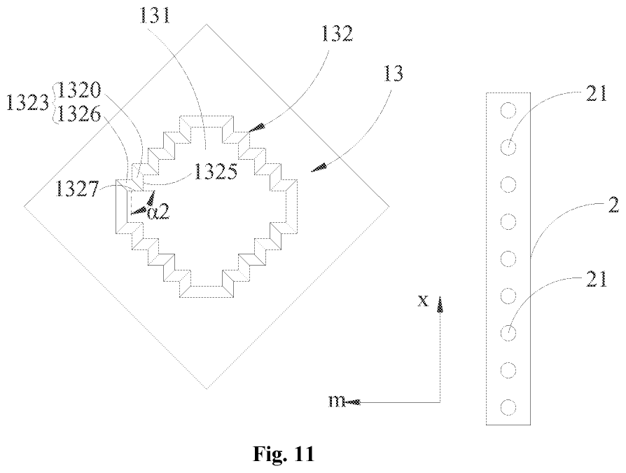

Specifically, the second electrode may be in contact with the first surface 1320 in the isolation structure 13. The display panel 1 according to the present application includes the substrate 11, the plurality of first scanning lines 111, the isolation structure 13, and the plurality of light-emitting functional units 121. The plurality of first scanning lines 111 are formed on the side of the substrate 11 and arranged along the first direction x to achieve scanning of a driving circuit corresponding to the light-emitting functional unit 121. The isolation structure 13 is formed on the side of the substrate 11 and encircles and forms the opening portion 131, the light-emitting functional unit 121 is formed within the opening portion 131, and the light-emitting functional unit 121 includes the first electrode 1211, the light-emitting functional layer 1212, and the second electrode 1213 stacked along a direction away from the substrate 11. The isolation structure 13 includes the first isolation portion 132 including the side surface 1323 facing the side of the opening portion 131, and the side surface 1323 includes the first surface 1320 and may further include other surfaces intersecting with the first surface 1320, which is not limited in the present application. The plane where the first surface 1320 is located intersects the plane where the substrate 11 is located to form the first intersection line 1325, or the first surface 1320 intersects a surface parallel to the plane where the substrate 11 is located to form a first intersection line 1325; and specifically, the first intersection line 1325 may be an edge line of the first surface 1320 close to one terminal of the substrate 11. As shown in FIG. 11, in a manufacturing process, an arrangement direction of various evaporation holes 21 on the evaporation source 2 configured to evaporate the second electrode 1213 is often parallel to the first direction x, in the display panel 1 according to the present application, the first intersection line 1325 and the first direction x forms the first preset angle, and the first preset angle is set to be greater than or equal to 0°, and less than 45°, so that an evaporation material evaporated from evaporation holes 21 in the evaporation source 2 arranged along a direction parallel to the first direction x may be distributed uniformly on the first surface 1320. Specifically, the “uniformly” means a strong consistency in a thickness distribution along the first intersection line 1325 in the first surface 1320, uniformity of the thickness distribution of a contact portion between the second electrode 1213 formed by the evaporation material and the first surface 1320 is increased, so that the resistance of various regions of second electrodes 1213 arranged along a first intersection line 1325 direction is more uniform. Meanwhile, an actual evaporation angle is relatively great, so that a height of the second electrode 1213 on the first surface 1320 is increased, an overlapped area between the isolation structure 13 and the second electrode 1213 is increased, brightness uniformity of light emitted by various parts of the light-emitting functional unit 121 is enhanced, the resistance is reduced, and overlapping stability is increased, which is helpful to improve a display quality of the display panel.

Here, the above “height” refers to a climbing distance of the evaporation material on the isolation structure 13. The climbing distance is a minimum distance that the evaporation material extends from one terminal close to the substrate 11 to the other terminal away from the substrate 11 on the first surface 1320.

Specifically, under a condition that the thickness distribution of the second electrode 1213 in the first surface 1320 along the first intersection line 1325 direction is more uniform, resistance differences at various positions of the light-emitting functional unit 121 may be relatively small, so that brightness uniformity of the light-emitting functional unit 121 may be increased. The height of the second electrode 1213 on the first surface 1320 is relatively great, and total resistance in the driving circuits configured to drive the light-emitting functional units 121 may be reduced, so that brightness of the light-emitting functional unit 121 is greater, which is beneficial for reducing the power consumption of the display panel 1. Meanwhile, a contact area between the first surface 1320 and the second electrode 1213 is greater, so that stability and reliability of the connection between the two are increased.

As shown in FIG. 11, in the manufacturing process of the display panel 1, the display panel 1 includes an under evaporation state (that is, a state before the second electrode 1213 is manufactured) before the manufacturing is completed. Due to limitation of a process device for processing and manufacturing, a relative position between the evaporation source 2 and the display panel 1 in the under evaporation state is fixed, an arrangement direction of the evaporation holes 21 in the evaporation source 2 is parallel to the first direction x, and a preset direction m of the evaporation source 2 is parallel to the substrate 11 and perpendicular to the first direction x. Changing the relative position between the evaporation source 2 and the display panel 1 in an under evaporation state causes a significant increase in production cost. In the above implementation, the side surface 1323 of the isolation structure 13 includes the first surface 1320, under a condition that an arrangement of the opening portion 131 within the display panel 1 and the relative position between the evaporation source 2 and the display panel 1 under evaporation are not changed, and only the a shape of the side walls of the opening portion 131 is changed, distribution uniformity of an overlapped portion between the second electrode 1213 and the first isolation portion 132 is improved, so that the manufacturing cost may be reduced while quality of the display panel is improved.

In the above implementation, a material of the isolation structure 13 is a conductive material, so that the second electrodes 1213 between adjacent light-emitting functional units 121 may be electrically connected, and a number of power supply lines of the second electrodes 1213 within the display panel 1 is reduced, thereby simplifying wiring within the display panel 1 and reducing the manufacturing cost.

In the above implementation, the substrate 11 may be formed of polymer materials such as glass, polyimide (PI), polycarbonate (PC), polyethersulfone (PES), polyethylene terephthalate (PET), polyethylene naphthalate (PEN), polyarylate (PAR), or glass fiber reinforced plastic (FRP). It may be transparent, translucent or opaque. The substrate 11 in the embodiments of the present application may also be a flexible substrate 11 formed of a relatively thin polymer, such as polyimide. The substrate 11 may further include a buffer layer that may include a plurality of layers of inorganic and organic stacked structures to block oxygen and moisture, prevent moisture or impurities from diffusing through the substrate 11, and provide a flat surface on an upper surface of the substrate 11. The specific structure is not described in detail in the present application.

In a feasible implementation, the first preset angle is greater than or equal to 0°, and less than 15°.

In the above implementation, under a condition that the first preset angle is 0°, the distribution uniformity of the evaporation material on the first surface 1320 is optimal. The first preset angle is set to be greater than or equal to 0°, and less than 15°, so that it may be ensured that the evaporation material evaporated from the evaporation holes arranged along the first direction x is distributed more uniformly on the first surface 1320 and has a relatively great height, and a deviation caused by the accuracy of the manufacturing process on the first preset angle is considered.

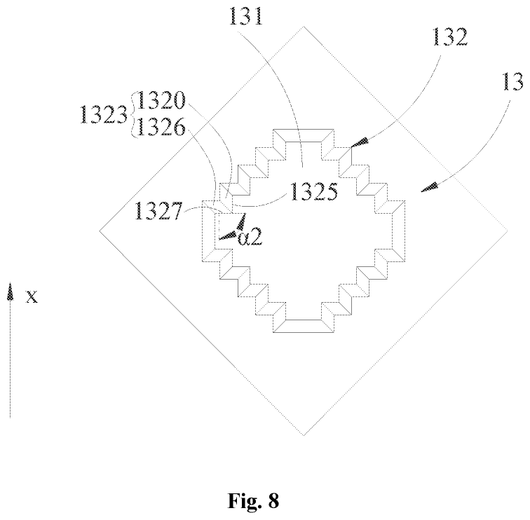

In a feasible implementation, as shown in FIG. 8, the first intersection line 1325 is parallel to the first direction x. Under this condition, the actual evaporation angle is the original evaporation angle of the evaporation source 2, and an evaporation effect is optimal. Therefore, under a condition that the relative position between the evaporation source 2 and the display panel 1 under evaporation is not changed, an overlapped area between the second electrode 1213 and the first separator 132 is increased, and resistance of the second electrode 1213 is reduced, so that the power consumption of the display panel 1 is reduced, light-emitting quality of the light-emitting functional unit 121 is increased, and production cost is considered.

In a feasible implementation, as shown in FIG. 7, the display panel 1 includes a plurality of data lines 112, and the plurality of data lines extend along the first direction x.

In a feasible implementation, the plurality of first scanning lines 111 extend along a second direction y, and the first direction x is perpendicular to the second direction y. In a feasible implementation, as shown in FIG. 10, the first isolation portion 132 includes a top surface 1321 and a bottom surface 1322 parallel to the substrate 11, the top surface 1321 is located on a side of the bottom surface 1322 away from the substrate 11, and the first surface 1320 is connected to the bottom surface 1322.

In the above implementation, the second electrode 1213 includes a first part 1214 located within the opening portion 131 encircled by the first isolation portion 132, and an orthographic projection of the first part 1214 on the substrate 11 does not overlap an orthographic projection of the first isolation portion 132 on the substrate 11. The second electrode 1213 further includes a second part 1215 in contact with the first surface 1320, and the first part 1214 is connected to the second part 1215. The first surface 1320 is connected to the bottom surface 1322 and extends from the bottom surface 1322 to the top surface 1321, so that a connection yield between the second part 1215 and the first part1214 on the first surface 1320 may be increased in a process of forming the second electrode 1213. Therefore, the connection of the first part 1214 to the second part 1215 may be achieved under a condition that a film thickness of the second electrode 1213 is not considered, and the manufacturing process may be simplified.

In a feasible implementation, as shown in FIG. 8, an edge of the orthographic projection of the first isolation portion 132 on the substrate 11 is in a sawtooth shape.

In the above implementation, the edge of the orthographic projection of the first isolation portion 132 on the substrate 11 is in the sawtooth shape means that an edge of an orthographic projection of an opening encircled by the first isolation portion 132 on the substrate 11 is in a sawtooth shape, so that different first surfaces 1320 may be connected and encircle and form the opening portion 131.

In a feasible implementation, as shown in FIG. 10, the first isolation portion 132 includes a first cross section 1324 perpendicular to the substrate 11, and the first cross section 1324 is in a positive trapezoid shape.

In the above implementation, the first cross section 1324 is in the positive trapezoid shape, that is, the side surface 1323 of the first isolation portion 132 is inclined relative to the plane where the substrate 11 is located, and a terminal of the side wall away from the substrate 11 is inclined to a direction away from a center of the opening portion 131 relative to a terminal close to the substrate 11, so that the side wall is more likely to bear the evaporation material, and the formed second electrode 1213 is more likely to be in contact with and connected to the side wall.

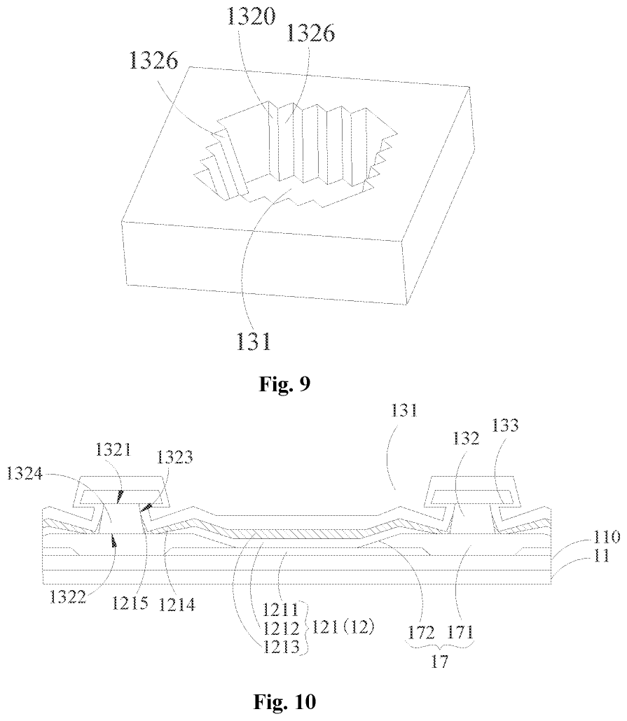

In a feasible implementation, as shown in FIG. 8 and FIG. 9, the side surface 1323 further includes a second surface 1326, the second surface 1326 and the first surface 1320 are provided alternately along a direction around the center of the opening portion 131, the second surface 1326 is connected to the first surface 1320, a plane where the second surface 1326 is located intersects the plane where the substrate 11 is located to form a second intersection line 1327, and the second intersection line 1327 and the first direction x form a second preset angle α2 greater than 45° and less than or equal to 90°.

In the above implementation, the side surface 1323 of the first isolation portion 132 further includes the second surface 1326, the second surface 1326 and the first surface 1320 are provided alternately along the direction around the center of the opening portion 131, and adjacent first surfaces 1320 are connected through the second surface 1326, thereby encircling and forming the opening portion 131, and achieving the design of the shape of the opening portion 131.

In the above implementation, the plane where the second surface 1326 is located intersects the plane where the substrate 11 is located to form the second intersection line 1327, or the second surface 1326 intersects the surface parallel to the plane where the substrate 11 is located to form the second intersection line 1327, and the second intersection line 1327 and the first direction x form the second preset angle α2 greater than 45° and less than or equal to 90°, that is, the second surface 1326 is less likely to receive the evaporation material than the first surface 1320, and a function of the second surface 1326 is only to connect the adjacent first surfaces 1320. The greater the second preset angle α2 is within its value range, the less the actual evaporation angle of the evaporation source 2 on the second surface 1326 is, and the closer a distance between two first surfaces 1320 connected to the evaporation source 2 along the first direction x is, so that under a condition that a size of the opening portion 131 along the first direction x is fixed, a ratio of a projection area of the first surface 1320 along the preset direction to a total projection area of the first surface 1320 and the second surface 1326 along the preset direction may be increased, and here, the preset direction is parallel to the substrate 11 and perpendicular to the first direction x. Therefore, a contact area between the first isolation portion 132 and the second electrode 1213 may be further increased.

In a feasible implementation, as shown in FIG. 8, the second preset angle α2 is equal to 90°.

In the above implementation, under a condition that the second preset angle α2 is 90°, the ratio of the projection area of the first surface 1320 along the preset direction to the total projection area of the first surface 1320 and the second surface 1326 along the preset direction is the greatest, and the effect is optimal.

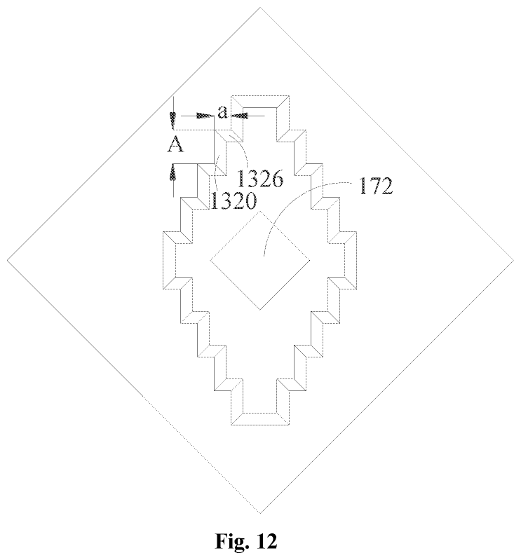

In a feasible implementation, as shown in FIG. 10 and FIG. 12, the first isolation portion 132 includes a top surface 1321 and a bottom surface 1322 parallel to the substrate 11, the top surface 1321 is located on a side of the bottom surface 1322 away from the substrate 11, and a length a of an intersection line of the second surface 1326 and the bottom surface 1322 is less than a length A of an intersection line of the first surface 1320 and the bottom surface 1322.

The first surface 1320 is configured to bear the evaporation material to form the second electrode 1213 in contact with the first isolation portion 132, and the second surface 1326 is configured to connect the adjacent first surfaces 1320, therefore, the length of the intersection line of the first surface 1320 and the bottom surface 1322 is greater than the length of the intersection line of the second surface 1326 and the bottom surface 1322, so that the overlapped area between the side wall and the second electrode 1213 may be increased, thereby improving an overlapping yield of the two.

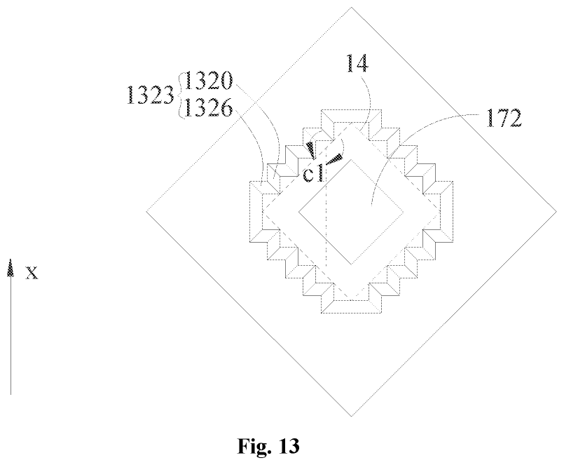

In a feasible implementation, as shown in FIG. 13, in the opening portion 131, an orthographic projection of one terminal of an intersection line of the first surface 1320 and the second surface 1326 close to the substrate 11 on the substrate 11 is located on a first virtual quadrilateral 14 or a virtual circle (not shown in the drawing), and a side edge of the first virtual quadrilateral 14 and the first direction x form a first angle c1 greater than 0° and less than 90°.

In the above implementation, in the opening portion 131, the orthographic projection of one terminal of the intersection line of the first surface 1320 and the second surface 1326 close to the substrate 11 on the substrate 11 is located on the first virtual quadrilateral 14 or the virtual circle, on the one hand, the manufacturing may be facilitated, and on the other hand, an effect of providing the first surface 1320 and the second surface 1326 on an opening rate may be reduced. Meanwhile, under a condition that the display panel 1 is a rectangular display panel 1, the rectangular display panel 1 often includes two side edges parallel to the first direction x and two side edges perpendicular to the first direction x, and the first angle c1 formed by the side edge of the first virtual quadrilateral 14 and the first direction x is set to be greater than 0° and less than 90°, so that a probability of poor display such as occurrence of a stripe in the display may be reduced, a sawtooth in the display may be reduced, and the display of an image may be improved.

In a feasible implementation, as shown in FIG. 13, the first virtual quadrilateral 14 is a rectangle, and the first angle c1 is 45°.

In the above implementation, the first angle c1 is 45°, so that the probability of display defects such as the occurrence of the stripe in the display may be further reduced, the sawtooth in the display may be reduced, and the display of the image may be improved.

In a feasible implementation, as shown in FIG. 1, the plurality of light-emitting functional units 121 include a plurality of first light-emitting functional units 1216, a plurality of second light-emitting functional units 1217, and a plurality of third light-emitting functional units 1218, each of first light-emitting functional units 1216 is located within a corresponding second virtual quadrilateral 18, two opposite apexes of the second virtual quadrilateral 18 respectively coincides with a center of the second light-emitting functional unit 1217, and the other two opposite apexes respectively coincides with a center of the third light-emitting functional unit 1218, and a number ratio of the first light-emitting functional units 1216, the second light-emitting functional units 1217, and the third light-emitting functional units 1218 is 2:1:1.

In such arrangement, shapes of corresponding second electrodes 1213 in various light-emitting functional units 121 are preferred to be the same to facilitate the manufacturing.

In the above implementation, a color of the first light-emitting function unit 1216 is green, a color of the second light-emitting function unit 1217 is red or blue, under a condition that the color of the second light-emitting function unit 1217 is red, a color of the third light-emitting function unit 1218 is blue, and under a condition that the color of the second light-emitting function unit 1217 is blue, the color of the third light-emitting function unit 1218 is red.

In the above implementation, under a condition that an arrangement of the light-emitting functional units 121 is not changed, the first isolation portion 132 is improved, and the first surface 1320 is formed on a side of the first isolation portion 132 facing inside the opening portion 131 to enhance an overlapping effect between the second electrode 1213 and the first isolation portion 132.

In a feasible implementation, as shown in FIG. 10, the isolation structure 13 further includes a second isolation portion 133 located on a side of the first isolation portion 132 away from the substrate 11, and an orthographic projection of the first isolation portion 132 on the substrate 11 is located within an orthographic projection of the second isolation portion 133 on the substrate 11.

In the isolation structure 13, the orthographic projection of the first isolation portion 132 on the substrate 11 is located within the orthographic projection of the second isolation portion 133 on the substrate 11, and an area of the orthographic projection of the second isolation portion 133 on the substrate 11 is greater than an area of the orthographic projection of the first isolation portion 132 on the substrate 11, so that a step portion is formed between the first isolation portion 132 and the second isolation portion 133. Under a condition that light-emitting functional units 121 of various colors are manufactured, various film layers in the light-emitting functional unit 121 of one color are integrally formed first, then the light-emitting functional unit 121 of the one color is formed in a designated opening portion 131 through etching, and opening portions configured to accommodate the light-emitting functional layers 1212 of other colors are exposed. The light-emitting functional units 121 of different colors are manufactured in different steps, and a fine metal mask does not need to be used in the above manufacturing process, so that the manufacturing cost may be reduced. The isolation structure 13 may be manufactured using a dark color material to have a light blocking effect, prevent an optical crosstalk between adjacent light-emitting functional units 121, and reduce a probability of emitting, from a light-emitting surface of the display panel 1, reflected light formed by reflecting external light by a structure under the isolation structure 13, thereby reducing a reflectivity of the display panel 1.

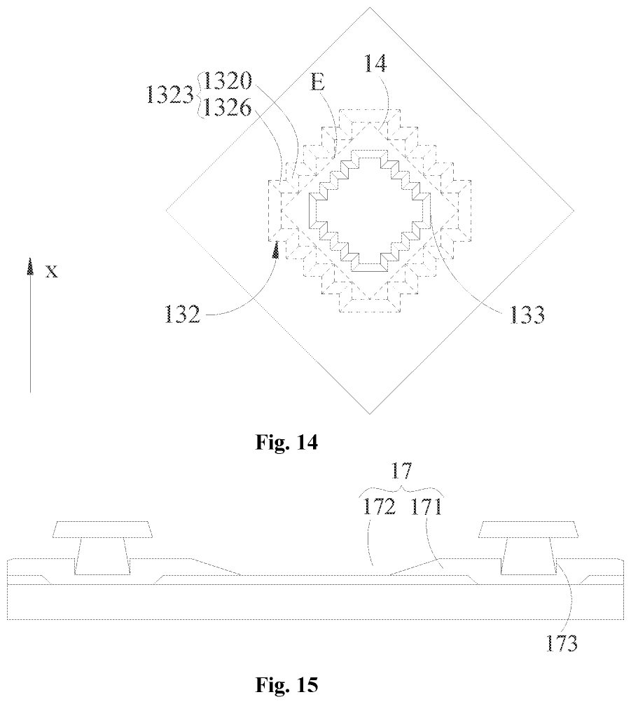

In a feasible implementation, as shown in FIG. 14, an edge of the orthographic projection of the second isolation portion 133 on the substrate 11 is in a sawtooth shape.

In the above implementation, the edge of the orthographic projection of the second isolation portion 133 on the substrate 11 is in the sawtooth shape means that an edge of an orthographic projection of an opening encircled by the second isolation portion 133 on the substrate 11 is in a sawtooth shape, so that a shape of the second isolation portion 133 may be adapted to a shape of the first isolation portion 132 by changing the shape of the second isolation portion 133, the sawtooth shape of the edge of the orthographic projection of the opening encircled by the second isolation portion 133 on the substrate 11 may be located within the sawtooth shape of the edge of the orthographic projection of the first isolation portion 132 on the substrate 11, and edges of the two sawtooth shapes are parallel to each other, and thus a blocking effect of the second isolation portion 133 on various positions of the first isolation portion 132 is the same, which is beneficial for increase height uniformity of the second electrode 1213.

In a feasible implementation, as shown in FIG. 10, the display panel 1 further includes a pixel definition layer 17 located on a side of the substrate 11, the pixel definition layer 17 includes a pixel definition portion 171 and a first opening 172 defined by the pixel definition portion 171, and at least a part of the light-emitting functional layer 1212 is provided within the first opening 172.

The pixel definition layer 17 may define a position of the light-emitting functional unit 121 and covers an edge of the first electrode 1211 to achieve insulation between the first electrodes 1211 and between the first electrode 1211 and the isolation structure 13.

The isolation structure 13 may be manufactured using a dark color material, under this condition, a light transmissive inorganic material may be used by the pixel definition layer 17 to further reduce material cost.

In a feasible implementation, as shown in FIG. 10, the isolation structure 13 is located on a side of the pixel definition portion 171 away from the base plate 11.

In a feasible implementation, as shown in FIG. 15, a groove 173 is provided on a side of the pixel definition portion 171 away from the substrate 11, and the isolation structure 13 is located within the groove 173. Therefore, a distance between a side of the isolation structure 13 away from the substrate 11 and a surface of the substrate 11 may be reduced, so that a blocking of large-angle light emitted by the light-emitting functional layer 1212 by the isolation structure 13 may be reduced, and display brightness of the display panel 1 may be increased.

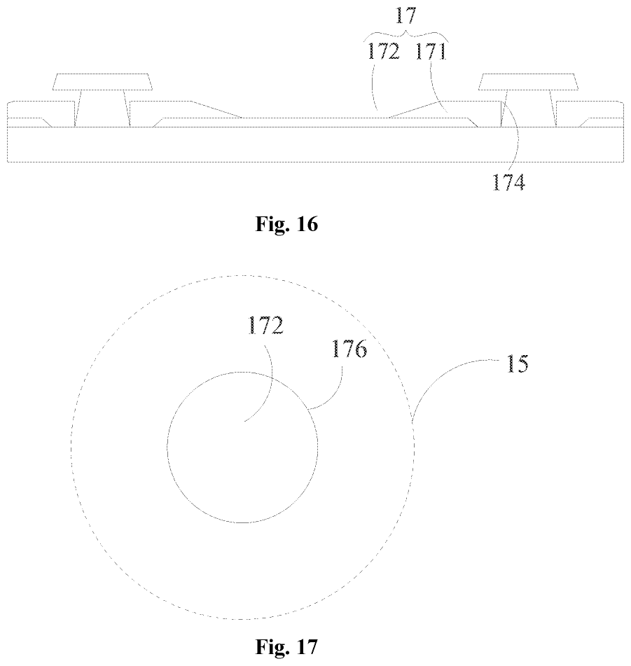

In a feasible implementation, as shown in FIG. 16, the pixel definition portion 171 includes a second opening 174, and the isolation structure 13 is located within the second opening 174. Here, the second opening 174 may be a via penetrating along a thickness direction of the pixel definition portion 171.

Providing the pixel definition layer 17 may achieve insulation between the first electrode 1211 and the isolation structure 13, and the pixel definition layer 17 may protect the first electrode 1211; under a condition that the first electrode 1211 includes a material susceptible to oxidation, such as silver, a probability of the first electrode 1211 being oxidized may be reduced. The isolation structure 13 is directly located on the substrate 11, so that the distance between the side of the isolation structure 13 away from the substrate 11 and the surface of the substrate 11 may be further reduced, and the blocking of the large angle light emitted by the light-emitting functional unit 121 by the isolation structure 13 may be reduced, so as to increase the display brightness of the display panel 1.

In a feasible implementation, the side surface 1323 further includes a second surface 1326, the second surface 1326 and the first surface 1320 are provided alternately along a circumferential direction of the opening portion 131, and the second surface 1326 is connected to the first surface 1320. As shown in FIG. 17, in the opening portion 131, an orthographic projection of one terminal of an intersection line of the first surface 1320 and the second surface 1326 close to the substrate 11 on the substrate 11 is located on a virtual circle 15, a shape of an orthographic projection of the first opening 172 on the substrate 11 includes a circle 176 coinciding with a center of the virtual circle 15.

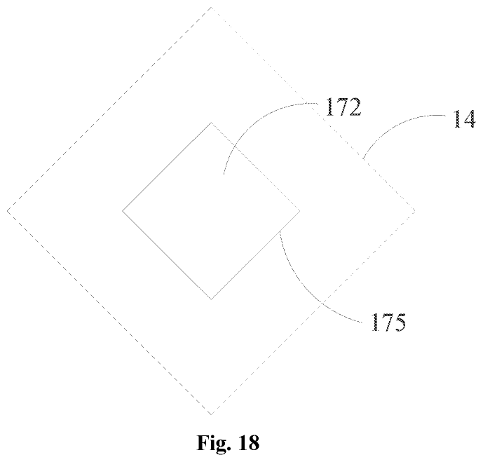

In another feasible implementation, the side surface 1323 further includes the second surface 1326, the second surface 1326 and the first surface 1320 are provided alternately along the circumferential direction of the opening portion 131, and the second surface 1326 is connected to the first surface 1320. As shown in FIG. 13 and FIG. 18, in the opening portion 131, the orthographic projection of the one terminal of the intersection line of the first surface 1320 and the second surface 1326 close to the substrate 11 on the substrate 11 is located on a first virtual quadrilateral 14, a shape of an orthographic projection of the first opening 172 on the substrate 11 includes a quadrilateral 175 coinciding with a center of the first virtual quadrilateral 14, one diagonal line of the quadrilateral 175 is collinear with one diagonal line of the first virtual quadrilateral 14, the other diagonal line of the quadrilateral 175 is collinear with the other diagonal line of the first virtual quadrilateral 14, and one side edge of the quadrilateral 175 and a corresponding side edge of the first virtual quadrilateral 14 form a second angle greater than or equal to 0°, and less than 15°.

In the above implementation, the orthographic projection of the one terminal of the intersection line of the first surface 1320 and the second surface 1326 close to the substrate 11 on the substrate 11 is located on the virtual circle 15 or the first virtual quadrilateral 14, a shape of the first opening 172 is the same as a shape of the virtual circle 15 or the first virtual quadrilateral 14, and widths of ring structures formed between the first opening 172 and the virtual circle 15 or the first virtual quadrilateral 14 are the same or similar, on the one hand, the manufacturing may be facilitated, and on the other hand, a better manufacturing of the isolation structure 13 may be achieved under a condition that a distance between the first openings 172 is ensured. Meanwhile, an opening rate of the display panel is increased to ensure the display effect.

A second aspect of the present application also provides a display panel 1, as shown in FIG. 10 and FIG. 14, the display panel 1 includes a substrate 11, an isolation structure 13, and a plurality of light-emitting functional units 121. The isolation structure 13 is formed on a side of the substrate 13 and encircles and forms an opening portion 131. The display panel 1 includes a plurality of light-emitting functional units 121, the light-emitting functional unit 121 is provided on the substrate 11 and corresponds to the opening portion 131, and the light-emitting functional unit 121 includes a first electrode 1211, a light-emitting functional layer 1212, and a second electrode 1213; here, the second electrode 1213 is in contact with the isolation structure 13, and an edge of an orthographic projection of the isolation structure 13 on the substrate 11 is in a sawtooth shape.

In the above implementation, the edge of the orthographic projection of the isolation structure 13 on the substrate 11 is in the sawtooth shape means that an edge of an orthographic projection of the opening portion 131 of the isolation structure 13 on the substrate 11 is in a sawtooth shape, so that the isolation structure 13 may include a surface easily bearing the evaporation material and a surface is not easily bearing the evaporation material. The surface easily bearing the evaporation material may improve a contact effect between the second electrode 1213 and the isolation structure 13, and the surface not easily bearing the evaporation material may be connected to adjacent surfaces easily bearing the evaporation material, so as to encircle and form the opening portion 131 and adjust a shape of the opening portion 131, so that a probability of display defects such as occurrence of a stripe in the display is reduced, a sawtooth in the display is reduced, and the display of an image is improved.

In a feasible implementation, as shown in FIG. 10, FIG. 14, FIG. 17, and FIG. 18, the display panel 1 further includes a pixel definition layer 17 located on a side of the substrate 11, the pixel definition layer 17 includes a pixel definition portion 171 and a first opening 172 defined by the pixel definition portion 171, and at least a part of the light-emitting functional layer 1212 is provided within the first opening 172.

A protruding terminal of the sawtooth shape of the edge of the orthographic projection of the isolation structure 13 on the substrate close to a center of the opening portion 131 is located on a virtual circle 15, and a shape of an orthographic projection of the first opening 172 on the substrate 11 includes a circle 176 coinciding with a center of the virtual circle 15.

Or, a protruding terminal of the sawtooth shape of the edge of the orthographic projection of the isolation structure 13 on the substrate 11 close to the center of the opening portion 131 is located on a first virtual quadrilateral 14, a shape of an orthographic projection of the first opening 172 on the substrate 11 includes a quadrilateral 175 coinciding with a center of the first virtual quadrilateral 14, one diagonal line of the quadrilateral 175 is collinear with one diagonal line of the first virtual quadrilateral 14, the other diagonal line of the quadrilateral 175 is collinear with the other diagonal line of the first virtual quadrilateral 14, and one side edge of the quadrilateral 175 and a corresponding side edge of the first virtual quadrilateral 14 form a second angle greater than or equal to 0°, and less than 15°.

In the above implementation, a protruding terminal E of the sawtooth shape of the edge of the orthographic projection of the opening portion 131 of the isolation structure 13 on the substrate 11 close to the center of the opening portion is located on the virtual circle 15 or the first virtual quadrilateral 14, a shape of the first opening 172 is the same as a shape of the virtual circle 15 or the first virtual quadrilateral 14, and widths of ring structures formed between the first opening 172 and the virtual circle 15 or the first virtual quadrilateral 14 are the same or similar, on the one hand, the manufacturing may be facilitated, and on the other hand, a better manufacturing of the isolation structure 13 may be achieved under a condition that a distance between the first openings 172 is ensured. Meanwhile, an opening rate of the display panel is increased to ensure the display effect.

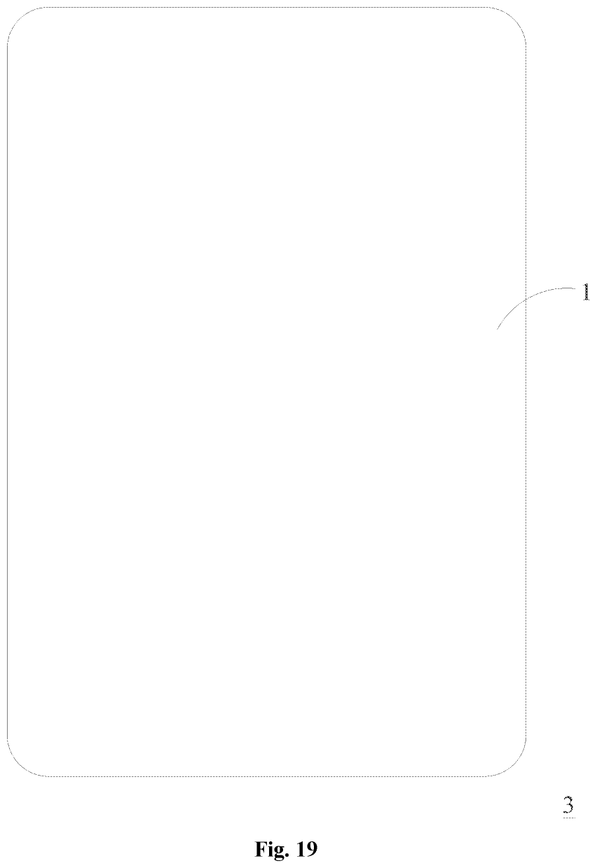

As shown in FIG. 19, the display apparatus 3 includes any of the display panels 1 according to the first aspect of the present application.

Since the display apparatus 3 according to the embodiments of the third aspect of the present application includes the display panel 1 according to any of the above embodiments of the first aspect and the second aspect, the display apparatus according to the embodiments of the third aspect of the present application has the beneficial effects of the display panel 1 according to any of the above embodiments of the first aspect and the second aspect, which is not repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

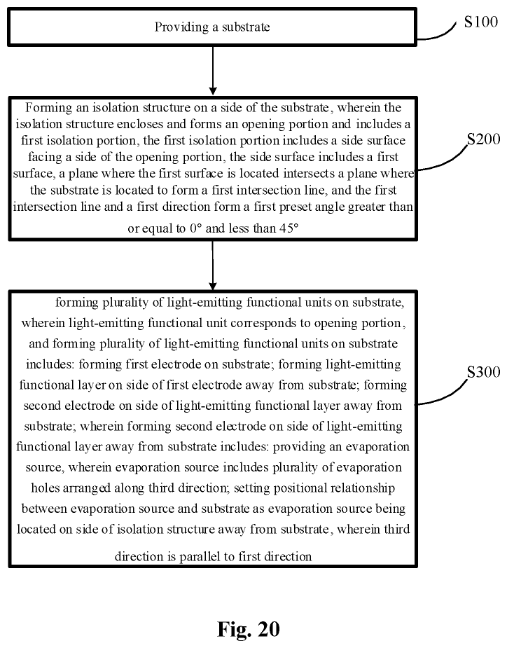

A fourth aspect of the present application provides a method for manufacturing a display panel 1, as shown in FIG. 20, the method includes:
S100, providing a substrate 11.

S200, forming an isolation structure 13 on a side of the substrate 11, here, the isolation structure 13 encircles and forms an opening portion 131 and includes a first isolation portion 132, the first isolation portion 132 includes a side surface 1323 facing a side of the opening portion 131, the side surface 1323 includes a first surface 1320, a plane where the first surface 1320 is located intersects a plane where the substrate 11 is located to form a first intersection line 1325, and the first intersection line 1325 and a first direction x form a first preset angle greater than or equal to 0°, and less than 45°.

S300, forming a plurality of light-emitting functional units 121 on the substrate 11, here, the light-emitting functional unit 121 corresponds to the opening portion 131, and forming the plurality of light-emitting functional units 121 on the substrate 11 includes: forming a first electrode 1211 on the substrate 11; forming a light-emitting functional layer 1212 on a side of the first electrode 1211 away from the substrate 11; forming a second electrode 1213 on a side of the light-emitting functional layer 1212 away from the substrate 11, here, forming the second electrode 1213 on the side of the light-emitting functional layer 1212 away from the substrate 11 includes: providing an evaporation source 2 including a plurality of evaporation holes arranged along a third direction; setting a positional relationship between the evaporation source 2 and the substrate 11 as the evaporation source 2 being located on a side of the isolation structure 13 away from the substrate 11, here, the third direction is parallel to the first direction X.

In the above method, by providing the first surface 1320 on a side of the first isolation structure 13 facing the opening portion 131, the plane where the first surface 1320 is located intersects the plane where the substrate 11 is located to form the first intersection line 1325, or the first surface 1320 intersects a surface parallel to the plane where the substrate 11 is located to form a first intersection line 1325, and the first intersection line 1325 and the first direction x form the first preset angle greater than or equal to 0°, and less than 45°. In a manufacturing process, an arrangement direction of evaporation holes in the evaporation source 2 is parallel to the first direction x, so that an actual evaporation angle between the evaporation source 2 and the first surface 1320 may be increased, the actual evaporation angle is close to or equal to an original evaporation angle of the evaporation source 2, a more uniform evaporation material with a greater height may be adhered on the first surface 1320, and an increase in an area of the second electrode 1213 and uniformity of the resistance are achieved, which is beneficial for improving the display quality of the display panel 1.

Since the display apparatus according to the embodiments of the fourth aspect of the present application is configured to form the display panel 1 according to any of the above embodiments of the first aspect and the second aspect, the display apparatus according to the embodiments of the fourth aspect of the present application has the beneficial effects of the display panel 1 according to any of the above embodiments of the first aspect and the second aspect, which is not repeated herein.

In the above implementation, a step between steps S100 and S200 includes:
forming a plurality of first scanning lines 111 on a side of the substrate 11, here, the plurality of first scanning lines 111 are arranged along the first direction x.

In the above implementation, the plurality of first scanning lines 111 arranged along the first direction x are formed on the substrate 11, and under a condition that the first surface 1320 is formed on the substrate 11, the manufacturing is performed using the first direction x defined by the first scanning lines 111 as a reference. In a process device for processing and manufacturing the existing display panel 1, the first direction x defined by the first scanning line 111 in the display panel 1 under evaporation is often set to be parallel to an arrangement direction of the evaporation holes in the evaporation source 2, so that under a condition that a relative position between the evaporation source 2 and the display panel 1 in an under evaporation state is not changed, an effect of forming the second electrode 1213 on the first surface 1320 may be improved based on a positional relationship between the first surface 1320 and the evaporation source 2. In a feasible implementation, forming the second electrode 1213 on the side of the light-emitting functional layer 1212 away from the substrate 11 further includes: moving the evaporation source 2 along a preset direction, to make an evaporation material evaporated from the evaporation hole is formed on the first surface 1320 to form the second electrode 1213 in contact with the first surface 1320, here, the preset direction is parallel to the plane where the substrate 11 is located and perpendicular to the first direction x.

In the above implementation, the evaporation source 2 moves along a preset direction m perpendicular to the first direction x, and formation of the evaporation material with a relatively great height and a relatively uniform thickness on two opposite side walls 1323 may be achieved, so that the second electrode 1213 having a relatively great overlapped area with the isolation structure 13 and a relatively uniform thickness is formed.

In a feasible implementation, the first preset angle is 0°, and the distribution uniformity of the evaporation material on the first surface 1320 is optimal. The first preset angle is set to be greater than or equal to 0°, and less than 15°, so that it may be ensured that the evaporation material evaporated from the evaporation holes arranged along the first direction x is distributed more uniformly on the first surface 1320 and has a relatively great height, and a deviation caused by the accuracy of the manufacturing process on the first preset angle is considered.

In a feasible implementation, the side surface 1323 further includes a second surface 1326, the second surface 1326 and the first surface 1320 are provided alternately along a direction around the center of the opening portion 131, the second surface 1326 is connected to the first surface 1320, a plane where the second surface 1326 is located intersects the plane where the substrate 11 is located to form a second intersection line, or the second surface 1326 intersects a surface parallel to the plane where the substrate 11 is located to form a second intersection line, and the second intersection line and the first direction x form a second preset angle greater than 45° and less than or equal to 90°; that is, the second surface 1326 is less likely to receive the evaporation material than the first surface 1320, and a function of the second surface 1326 is only to connect the adjacent first surfaces 1320. The greater the second preset angle α2 is within its value range, the less the actual evaporation angle of the evaporation source 2 on the second surface 1326 is, and the closer a distance between two first surfaces 1320 connected to the evaporation source 2 along the first direction x is, so that under a condition that a size of the opening portion 131 along the first direction x is fixed, a ratio of a projection area of the first surface 1320 along the preset direction to a total projection area of the first surface 1320 and the second surface 1326 along the preset direction may be increased, and here, the preset direction is parallel to the substrate 11 and perpendicular to the first direction x. Therefore, a contact area between the first isolation portion 132 and the second electrode 1213 may be further increased.

In a feasible implementation, a length of an intersection line of the second surface 1326 and the bottom surface 1322 is less than a length of an intersection line of the first surface 1320 and the bottom surface 1322; the first surface 1320 is configured to bear the evaporation material to form the second electrode 1213 in contact with the first isolation portion 132, and the second surface 1326 is configured to connect the adjacent first surfaces 1320, therefore, the length of the intersection line of the first surface 1320 and the bottom surface 1322 is greater than the length of the intersection line of the second surface 1326 and the bottom surface 1322, so that the overlapped area between the side wall and the second electrode 1213 may be increased, thereby improving an overlapping yield of the two.

In a feasible implementation, the edge of the orthographic projection of the first isolation portion 132 on the substrate 11 is in the sawtooth shape means that an edge of an orthographic projection of an opening encircled by the first isolation portion 132 on the substrate 11 is in a sawtooth shape, so that different first surfaces 1320 may be connected and encircle and form the opening portion 131.

The above embodiments of the present application do not exhaustively describe all the details and do not limit the present application to the specific embodiments as described. Obviously, many modifications and variations can be made based on the above description. These embodiments are selected and specifically described in the description to better explain the principles and practical applications of the present application, so that those skilled in the art can make good use of the present application and make modifications based on the present application. The present application is limited only by the claims, along with their full scope and equivalents.

What is claimed is:

1. A display panel, comprising:
a substrate,
a plurality of first scanning lines located on a side of the substrate and arranged along a first direction;
at least an isolation structure formed on a side of the substrate and forming at least an opening portion, wherein the at least an isolation structure comprises a first isolation portion comprising a side surface facing a side of the at least an opening portion, the side surface comprises a first surface intersecting with a surface parallel to a plane where the substrate is located to form a first intersection line, and the first intersection line and the first direction form a first preset angle therebetween; and
a plurality of light-emitting functional units, wherein the light-emitting functional unit is provided on the substrate and corresponds to the at least an opening portion, and the light-emitting functional unit comprises a first electrode, a light-emitting functional layer, and a second electrode;
wherein the second electrode is in contact with the at least an isolation structure, and the first preset angle is greater than or equal to 0°, and less than 45°.

2. The display panel according to claim 1, wherein the first preset angle is greater than or equal to 0°, and less than 15°;
and the first intersection line is parallel to the first direction.

3. The display panel according to claim 1, wherein the display panel comprises a plurality of data lines extending along the first direction; and
the plurality of first scanning lines extend along a second direction, and the first direction is perpendicular to the second direction.

4. The display panel according to claim 1, wherein the first isolation portion comprises a top surface and a bottom surface parallel to the substrate, the top surface is located on a side of the bottom surface away from the substrate, and the first surface is connected to the bottom surface.

5. The display panel according to claim 1, wherein an edge of an orthographic projection of an opening encircled by the first isolation portion on the substrate is in a sawtooth shape.

6. The display panel according to claim 5, wherein the first isolation portion comprises a first cross section perpendicular to the substrate, and the first cross section is in a positive trapezoid shape.

7. The display panel according to claim 1, wherein the side surface further comprises a second surface, the second surface and the first surface are provided alternately along a direction around a center of the at least an opening portion, the second surface is connected to the first surface and intersects the surface parallel to the plane where the substrate is located to form a second intersection line, and the second intersection line and the first direction form a second preset angle greater than 45° and less than or equal to 90°.

8. The display panel according to claim 7, wherein the second preset angle is equal to 90°.

9. The display panel according to claim 7, wherein the first isolation portion comprises a top surface and a bottom surface parallel to the substrate, the top surface is located on a side of the bottom surface away from the substrate, and a length of an intersection line of the second surface and the bottom surface is less than a length of an intersection line of the first surface and the bottom surface;
in the at least an opening portion, an orthographic projection of one terminal of an intersection line of the first surface and the second surface close to the substrate on the substrate is located on a first virtual quadrilateral or a virtual circle, and a side edge of the first virtual quadrilateral and the first direction form a first angle greater than 0° and less than 90°.

10. The display panel according to claim 9, wherein in the at least an opening portion, the orthographic projection of the one terminal of the intersection line of the first surface and the second surface close to the substrate on the substrate is located on the first virtual quadrilateral, the side edge of the first virtual quadrilateral and the first direction form the first angle; wherein the first virtual quadrilateral is a rectangle, and the first angle is 45°.

11. The display panel according to claim 1, wherein the plurality of light-emitting functional units comprise a plurality of first light-emitting functional units, a plurality of second light-emitting functional units, and a plurality of third light-emitting functional units, each of the first light-emitting functional units is located within a corresponding second virtual quadrilateral, two opposite apexes of the second virtual quadrilateral respectively coincides with a center of the second light-emitting functional unit, and the other two opposite apexes respectively coincides with a center of the third light-emitting functional unit, and a number ratio of the first light-emitting functional units, the second light-emitting functional units, and the third light-emitting functional units is 2:1:1.

12. The display panel according to claim 1, wherein the at least an isolation structure further comprises a second isolation portion located on a side of the first isolation portion away from the substrate, and an orthographic projection of the first isolation portion on the substrate is located within an orthographic projection of the second isolation portion on the substrate.

13. The display panel according to claim 12, wherein an edge of an orthographic projection of an opening encircled by the second isolation portion on the substrate is in a sawtooth shape.

14. The display panel according to claim 1, wherein the display panel further comprises a pixel definition layer located on a side of the substrate, the pixel definition layer comprises a pixel definition portion and a first opening defined by the pixel definition portion, and at least a part of the light-emitting functional layer is provided within the first opening.

15. The display panel according to claim 14, wherein the at least an isolation structure is located on a side of the pixel definition portion away from the substrate; or
a groove is provided on a side of the pixel definition portion away from the substrate, and the at least an isolation structure is located within the groove; or
the pixel definition portion comprises a second opening, and the at least an isolation structure is located within the second opening.

16. The display panel according to claim 14, wherein the side surface further comprises a second surface, the second surface and the first surface are provided alternately along a direction around a center of the at least an opening portion, and the second surface is connected to the first surface;
in the at least an opening portion, an orthographic projection of one terminal of an intersection line of the first surface and the second surface close to the substrate on the substrate is located on a virtual circle, a shape of an orthographic projection of the first opening on the substrate comprises a circle coinciding with a center of the virtual circle; or
in the at least an opening portion, the orthographic projection of the one terminal of the intersection line of the first surface and the second surface close to the substrate on the substrate is located on a first virtual quadrilateral, a shape of an orthographic projection of the first opening on the substrate comprises a quadrilateral coinciding with a center of the first virtual quadrilateral, one diagonal line of the quadrilateral is collinear with one diagonal line of the first virtual quadrilateral, the other diagonal line of the quadrilateral is collinear with the other diagonal line of the first virtual quadrilateral, one side edge of the quadrilateral and a corresponding side edge of the first virtual quadrilateral form a second angle greater than or equal to 0°, and less than 15°.

17. A display panel, comprising:
a substrate,
at least an isolation structure formed on a side of the substrate and enclosing and forming at least an opening portion;
a plurality of light-emitting functional units, wherein the light-emitting functional unit is provided on the substrate and corresponds to the at least an opening portion, and the light-emitting functional unit comprises a first electrode, a light-emitting functional layer, and a second electrode;
wherein the second electrode is in contact with the at least an isolation structure, and an edge of an orthographic projection of the at least an opening portion on the substrate is in a sawtooth shape.

18. The display panel according to claim 17, wherein the display panel further comprises a pixel definition layer located on a side of the substrate, the pixel definition layer comprises a pixel definition portion and a first opening defined by the pixel definition portion, and at least a part of the light-emitting functional layer is provided within the first opening;
a protruding terminal of the sawtooth shape of the edge of the orthographic projection of the at least an opening portion on the substrate close to a center of the at least an opening portion is located on a virtual circle, and a shape of an orthographic projection of the first opening on the substrate comprises a circle coinciding with a center of the virtual circle; or
a protruding terminal of the sawtooth shape of the edge of the orthographic projection of the at least an opening portion on the substrate close to the center of the at least an opening portion is located on a first virtual quadrilateral, a shape of an orthographic projection of the first opening on the substrate comprises a quadrilateral coinciding with a center of the first virtual quadrilateral, one diagonal line of the quadrilateral is collinear with one diagonal line of the first virtual quadrilateral, the other diagonal line of the quadrilateral is collinear with the other diagonal line of the first virtual quadrilateral, and one side edge of the quadrilateral and a corresponding side edge of the first virtual quadrilateral form a second angle greater than or equal to 0°, and less than 15°.

19. A method for manufacturing a display panel, comprising:
providing a substrate;
forming at least an isolation structure on a side of the substrate, wherein the at least an isolation structure forms at least an opening portion and comprises a first isolation portion, the first isolation portion comprises a side surface facing a side of the at least an opening portion, the side surface comprises a first surface intersecting with a surface parallel to a plane where the substrate is located to form a first intersection line, and the first intersection line and a first direction form a first preset angle greater than or equal to 0°, and less than 45°;
forming a plurality of light-emitting functional units on the substrate, wherein the light-emitting functional unit corresponds to the at least an opening portion, wherein the forming the plurality of light-emitting functional units on the substrate comprises: forming a first electrode on the substrate; forming a light-emitting functional layer on a side of the first electrode away from the substrate; forming a second electrode on a side of the light-emitting functional layer away from the substrate;
wherein the forming the second electrode on the side of the light-emitting functional layer away from the substrate comprises:
providing an evaporation source comprising a plurality of evaporation holes arranged along a third direction; setting a positional relationship between the evaporation source and the in substrate as the evaporation source being located on a side of the at least an isolation structure away from the substrate, wherein the third direction is parallel to the first direction.

20. The method according to claim 19, wherein the first preset angle is 0°.

21. The method according to claim 19, wherein the side surface further comprises a second surface, the second surface and the first surface are provided alternately along a direction around a center of the at least an opening portion, the second surface is connected to the first surface and intersects with the surface parallel to the plane where the substrate is located to form a second intersection line, and the second intersection line and the first direction form a second preset angle greater than 45°, and less than or equal to 90°.

22. The method according to claim 19, wherein the forming the second electrode on the side of the light-emitting functional layer away from the substrate further comprises: moving the evaporation source along a preset direction, to make an evaporation material evaporated from the evaporation hole is formed on the first surface to form the second electrode in contact with the first surface, wherein the preset direction is parallel to the plane where the substrate is located and perpendicular to the first direction.

23. The method according to claim 19, further comprising: forming a plurality of first scanning lines on a side of the substrate, wherein the plurality of first scanning lines are arranged along the first direction.
